(19) United States
(12) Patent Application Publication
(10) Pub. No.: US 2007/0024158 A1
(43) Pub. Date: Feb. 1, 2007

(54) Integrated resonators and time base incorporating said resonators

(76) Inventor: Claude Bourgeois, Bole (CH)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/556,831

(22) PCT Filed: Apr. 28, 2004
(86) PCT No.: PCT/CH04/00258

§ 371 Date: Nov. 15, 2005

(30) Foreign Application Priority Data
May 15, 2003 (FR) 03/05833

(51) Int. Cl. H01L 41/00

(52) U.S. Cl. 310/321

(57) ABSTRACT

The invention relates to a set of resonators integrated in a single-crystal silicon substrate and intended to allow the production of a temperature stable time base. In one implementation, first and second resonators are designed to oscillate in modes of different type and with dimensions such that at least a first thermal coefficient α of their frequency difference is equal or close to zero, and a second thermal coefficient β may also be highly reduced.

The present invention relates to resonators in general and more particularly to integrated resonators made of single-crystal silicon, allowing the production of a temperature-stable time base, and to a time base produced with such resonators.

Quartz is certainly the material most widely used for the fabrication of resonators as this is one of the rare known crystals that allow the first thermal coefficient of the frequency to be canceled out, at room temperature, by a suitable choice of the cut angles of the resonators. In addition, it is also possible to compensate for the thermal drift, due to the higher-order coefficients, by adapting the very geometry of these resonators. Finally, the quartz is also piezoelectric, allowing direct excitation of the chosen vibration modes. Although quartz remains a material of choice for the production of resonant structures, there is, however, a growing demand for integrating such structures into a silicon substrate—the material used for integrated circuits and for an increasing number of structures of the MEMS (micro-electromechanical systems) type.

An example of a resonator integrated into a single-crystal silicon substrate may be found in European patent application EP 0 795 953. The thermal coefficients of the frequency of such a resonator are, respectively, around −30 ppm (parts per million or 10⁻⁶)/° C. for the first-order coefficient α and −13 ppb (parts per billion or 10⁻⁹)/° C.² for the second-order coefficient β. To compensate for them, it has been proposed to use a thermometer, integrated into the same substrate, which acts on a frequency adjustment circuit. Not only does such a compensation method involve calibration of the resonator/oscillator combination after fabrication, but in addition its precision depends on that of the integrated thermometer, which is far from ideal, in particular if the ageing effects are considered.

Thus, it is an object of the present invention to produce resonators which are integrated into a single-crystal silicon substrate and the thermal drift of which may be compensated in a simple and precise manner.

One subject of the invention is a set of resonators that are integrated in a single-crystal silicon substrate and intended to allow a temperature-stable time base to be produced, characterized in that it comprises at least first and second resonators designed to oscillate in modes of different type and with dimensions such that at least the first thermal coefficient of their frequency difference is equal or close to zero.

According to another feature of the invention, the second thermal coefficient of the frequency difference is also made close to zero by a given orientation of the resonators in the silicon substrate.

Thanks to these features, the thermal compensation is obtained by the frequency difference of two resonators oscillating in modes of different type, it being possible for this difference to be made independent of the temperature.

The set of resonators according to the invention also possesses all or some of the features mentioned below:
said first resonator is designed to oscillate in an elongation mode;
said second resonator is designed to oscillate in a surface shear mode;
said first and second resonators each have a symmetrical structure formed by a central arm joining two rectangular plates, said resonators being able to be held in the middle part of said central arms;
said resonators include piezoelectric excitation means;
said piezoelectric excitation means comprise an AlN layer deposited on said central arms and electrodes for contacting said AlN layer;
the silicon substrate is doped and constitutes one of the electrodes for said piezoelectric excitation means.

Other objects, features and advantages of the present invention will become apparent on reading the following description, given by way of non limiting example and in conjunction with the appended drawings in which:

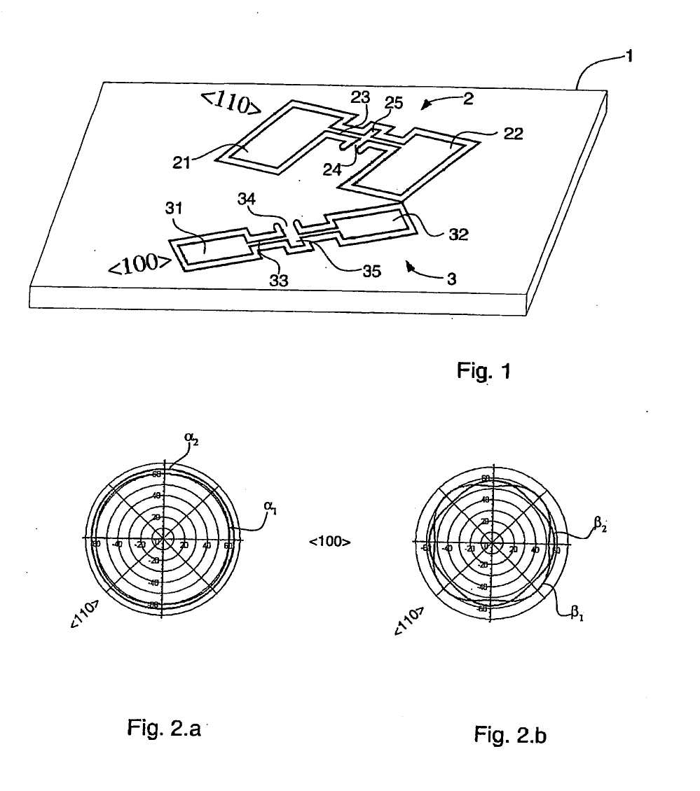

FIG. 1 shows a set of two resonators according to the invention that are produced in a single-crystal silicon wafer of {001} orientation;

FIGS. 2.a and 2.b show the variations in the first and second thermal coefficients, respectively, of the resonators of FIG. 1 as a function of the orientation of these resonators;

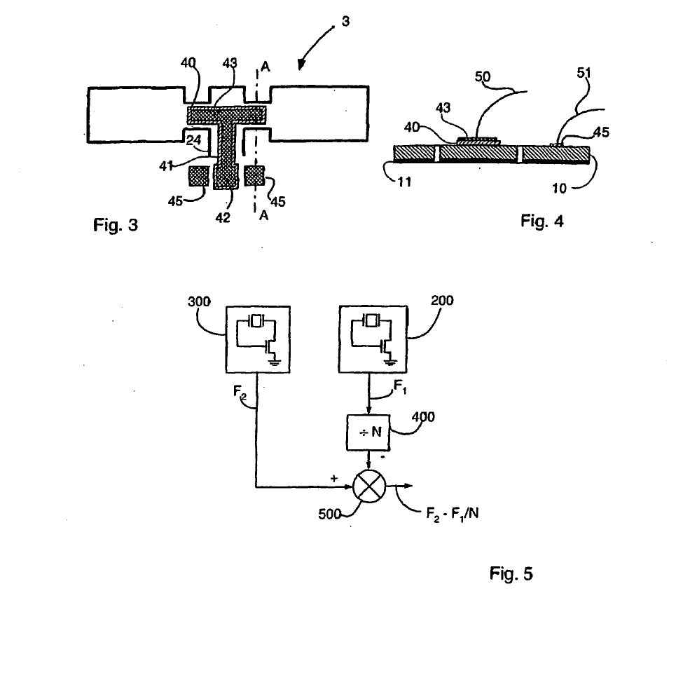

FIG. 3 shows the geometry of the AlN layers and of the electrodes deposited on the resonator 3 of FIG. 1;

FIG. 4 shows a sectional view of the resonator of FIG. 3; and

FIG. 5 is an example of a circuit for extracting the frequency difference of the resonators of the invention.

The two resonators 2 and 3 of FIG. 1 oscillate in modes called “contour modes”. This means that they take the form of thin plates vibrating in their plane and the frequency of which is independent of the thickness of said plates. Their structure corresponds to two rectangular plates 21, 22, 31, 32 joined by a central arm 23, 33, which is itself connected to the single-crystal silicon substrate 1 via an attachment arm 24, 34. A rectangular region 25, 35, located in the extension of and opposite the attachment arm, has the purpose of making each entire resonator symmetrical and, consequently, making its deformations symmetrical by counterbalancing the evanescence in the embedding region, and to do so for the purpose of achieving high quality factors. In the example described, the resonator 2 is designed to oscillate in a Lamé mode—the shear wave associated with it propagating along the diagonals of the squares inscribed within the plates 21 and 22—and it is oriented along the <110> direction of the substrate, whereas the resonator 3, with its longitudinal axis aligned with the <100> direction of the substrate, is designed to oscillate with its central arm 33 in an elongation mode.

According to the invention, the thermal compensation is achieved by the frequency difference of two resonators oscillating in different modes. The frequency of the resonator 2 may be expressed in the form:
F₁=F₁₀(1+α₁ΔT+β₁ΔT²+γ₁ΔT³+ . . . ),
where F₁₀ is the natural frequency of the resonator 2, ΔT is the temperature variation and α₁, β₁ and γ₁ are the respective first-order, second-order and third-order thermal coefficients of the frequency F₁.

The frequency of the resonator 3 may likewise be expressed in the form:
F₂=F₂₀(1+α₂ΔT+β₂ΔT²+γ₂ΔT³+ . . . ),
where F₂₀ is the natural frequency of the resonator 3, ΔT is the temperature variation and α₂, β₂ and γ₂ are the respective first-order, second-order and third-order thermal coefficients of the frequency F₂.

The frequency difference F₁₂ may therefore be written as
F₂=F₁−F₂=(F₁₀−F₂₀)(1+αΔT+βΔT²+γΔT³+ . . . )
where:

$$α = \frac{{F}_{10} α 1 - {F}_{20} α 2}{{F}_{10} - {F}_{20}} , \\ β = \frac{{F}_{10} {β}_{1} - {F}_{20} {β}_{2}}{{F}_{10} - {F}_{20}} , \\ and$$

$$γ = \frac{{F}_{10} {γ}_{1} - {F}_{20} {γ}_{2}}{{F}_{10} - {F}_{20}} .$$

The first thermal coefficient is therefore compensated by setting:

$${F}_{10} {α}_{1} - {F}_{20} {α}_{2} = 0$$

$$i . e . \\ \frac{{F}_{10}}{{F}_{20}} = \frac{{α}_{2}}{{α}_{1}} ,$$

the second thermal coefficient then being equal to:

$$β = \frac{{α}_{2} {β}_{1} - {α}_{1} {β}_{2}}{{α}_{2} - {α}_{1}}$$

The above equation shows that β is better controlled the greater the difference between α₁ and α₂. To optimize the way in which the canceling-out of first thermal coefficient α of the frequency difference F₁₂ is controlled, the vibration modes of the two resonators 2 and 3 are chosen in such a way that the first-order thermal coefficients that are associated with them are also as different as possible from each other. Thus, according to an advantageous variant of the invention, the vibration mode of the first resonator is a surface shear mode, subtended by a Lamé mode, whereas the vibration mode of the second resonator is an elongation mode. The precision of the first thermal coefficient α depends on the ratio of the frequencies of the two resonators, i.e. on a dimensional ratio of the resonators and not on a ratio of their absolute dimensions. Since the two resonators are produced on the same substrate, this first thermal coefficient is in fact largely insensitive to underetching effects or to cutting errors.

The expression for the second thermal coefficient β of the frequency difference F₁₂ shows that this can be canceled out, or greatly reduced, by choosing a β₁/β₂ ratio equal to, or close to, the ratio α₁/α₂. This condition may be met by a judicious choice of the orientations of the two resonators. FIGS. 2.a and 2.b show, for the two vibration modes chosen, the variations in the first and second thermal coefficients α₁ and α₂, β₁ and β₂, respectively, as a function of the orientations of the resonators. Although the first-order thermal coefficients vary little with orientation, the same does not apply to the second-order coefficients, and it may be seen that the condition indicated above can be met when the orientations of the resonators make an angle of about 45° with each other, the shear and elongation waves then propagating along the <100> direction.

The planar structures, with balanced evanescence regions, and the envisaged vibration modes of the resonators make it possible to obtain high quality factors. This makes it possible to produce low-consumption time bases (resonators and oscillators). Moreover, in order to greatly attenuate the coupling with the lower-frequency vibration modes, the resonator 2 may be produced by having masses 21 and 22 in the form of a stack of (at least two) square plates without, however, this modifying the frequency of the Lamé mode. This is one property of Lamé modes that can be put to advantage in order to increase the efficiency of the resonator/oscillator combination.

The resonators may be excited, in a known manner, by a coupling of the electrostatic type or piezoelectric type. According to an advantageous variant of the invention, the resonators are excited by a piezoelectric effect, for example via a layer of aluminum nitride (AlN). As indicated in FIG. 3 showing, for example, the resonator 3, the piezoelectric coupling is achieved via an AlN layer 40 deposited in the central region of the arm, at the point where the elongation deformations are the highest. This rectangular zone of about 225 μm×950 μm is extended along the attachment arm 24 by means of a thin strip 41 as far as a connection zone 42, having sides of about 120 μm, and to which a connection wire can be soldered. As shown in the sectional view of FIG. 4, along the axis A-A of FIG. 3, the aluminum nitride layer 40 is covered with an aluminum layer 43, which layer is also deposited directly on the substrate in order to form the pads 45 for connection to said substrate. If the silicon forming the substrate were not to be doped, it would be necessary to provide a second electrode between the substrate and the aluminum nitride layer. This second electrode is preferably made of platinum, a material that lends itself particularly well to the growth of aluminum nitride. FIG. 4 also shows the fact that the substrate is in fact a silicon wafer 10 whose lower face is made of silicon oxide. Such wafers, called SOI (silicon-on-insulator) wafers, already have the desired thickness. As was mentioned previously, the thickness of the resonators is a relatively free parameter, which is determined depending on the application. Thus, a large thickness makes it possible to have a high impact strength and reduced coupling with other vibration modes out of the plane, whereas a small thickness allows strong piezoelectric coupling, and therefore low consumption of the oscillator. By way of a non limiting example, the resonators have a thickness of about 50 μm.

The steps in the fabrication of the resonators are given below by way of non limiting example:
Deposition, by sputtering, of a platinum (Pt) film about 100 nm thick on the upper face (A) of the silicon substrate;
structuring of the platinum film, by photolithography and plasma etching, in order to produce the first electrodes;
deposition by sputtering of an aluminum nitride layer (a few μm in thickness);
deposition by sputtering of an aluminum film (about 100 nm thick) and selective machining of this film in order to produce the second electrodes;
etching of the AlN layer in order to define the piezoelectric excitation zones;
rapid plasma etching (or deep reactive ion etching) of the face A in order to define the geometry of the resonators;
optionally, cutting of the resonators by sawing; and
creation of a vacuum and connection of the resonators to their associated circuit.

As an indication, the parameters of the resonators are given below:

For the resonator 2:
dimensions of the plates: 2×1 mm;
length of the central arm: 1 mm;
frequency: ≈4 MHz.

For the resonator 3:
overall length: 2.5 mm;
length of the central arm: 1.2 mm;
frequency: ≈1 MHz.

An example of a circuit for delivering a temperature-stable frequency using the resonators described above is shown schematically in FIG. 5. The block 200 represents the combination of the resonator 2 and the oscillator associated therewith and the block 300 represents the combination of the resonator 3 and the oscillator associated therewith. The block 200 delivers a signal at the frequency F₁ and the block 300 delivers a signal at the frequency F₂, the frequency F₁ being, in the example described in which the two resonators have similar dimensions, higher than the frequency F₂ (about 4 times higher). The frequency F₁ is therefore divided by a frequency divider circuit 400, which delivers a signal at the frequency F₁/N, where N is an integer (equal to 4 in the example in question), which represents the division ratio of the divider circuit 400. The signals output by the block 300 and the divider circuit 400 are applied to the circuit 500, which delivers the difference F₂−F₁/N. As indicated above, this frequency difference is independent of the temperature variation and can therefore be used to produce a precise, stable and integrated time base, this being able to be used in many applications, in particular in portable applications.

Although the present invention has been described in relation to particular embodiment examples, it will be understood that it is capable of modifications or variants without thereby departing from its scope. Thus, although silicon was adopted for the present description, the resonators of the invention could be produced in other single crystals. Likewise, the chosen vibration modes must be considered merely as non limiting examples.

1-11. (canceled)

12. A set of resonators that are integrated in a single crystal and intended to allow a temperature-stable time base to be produced, the set of resonators comprising at least first and second resonators designed to oscillate in modes of different type and with dimensions such that their frequency difference has at least a first thermal coefficient α equal or close to zero.

13. The set of resonators as claimed in claim 12, wherein said single crystal is a single crystal silicon substrate.

14. The set of resonators as claimed in claim 12, wherein said first and second resonators are oriented at an angle such that said frequency difference has a second thermal coefficient β equal or close to zero.

15. The set of resonators as claimed in claim 13, wherein said first and second resonators are oriented at an angle such that said frequency difference has a second thermal coefficient β equal or close to zero.

16. The set of resonators as claimed in claim 12, wherein said first resonator is designed to oscillate in an elongation mode.

17. The set of resonators as claimed in claim 13, wherein said first resonator is designed to oscillate in an elongation mode.

18. The set of resonators as claimed in claim 15, wherein said first resonator is designed to oscillate in an elongation mode.

19. The set of resonators as claimed in claim 12, wherein said second resonator is designed to oscillate in a Lamé mode.

20. The set of resonators as claimed in claim 15, wherein said second resonator is designed to oscillate in a Lamé mode.

21. The set of resonators as claimed in claim 18, wherein said second resonator is designed to oscillate in a Lamé mode.

22. The set of resonators as claimed in claim 12, wherein said first and second resonators each have a symmetrical structure formed by a central arm joining two rectangular plates, said resonators being able to be held in the middle part of said central arms.

23. The set of resonators as claimed in claim 21, wherein said first and second resonators each have a symmetrical structure formed by a central arm joining two rectangular plates, said resonators being able to be held in the middle part of said central arms.

24. The set of resonators as claimed in claim 12, wherein said resonators include piezoelectric excitation means.

25. The set of resonators as claimed in claim 23, wherein said resonators include piezoelectric excitation means

26. The set of resonators as claimed in claim 24, wherein said piezoelectric excitation means comprise an AlN layer deposited on said central arms and electrodes for contacting, on the one hand, said AlN layer and, on the other hand, said silicon substrate.

27. The set of resonators as claimed in claim 25, wherein said piezoelectric excitation means comprise an AlN layer deposited on said central arms and electrodes for contacting, on the one hand, said AlN layer and, on the other hand, said silicon substrate.

28. The set of resonators as claimed in claim 27, wherein said silicon substrate is doped and constitutes one of said electrodes for said piezoelectric excitation means.

29. A temperature-compensated time base comprising a set of resonators as claimed in claim 12, means for exciting and sustaining their oscillations and means for generating a temperature-stable signal representative of the difference in oscillation frequencies of said resonators.

30. A temperature-compensated time base comprising a set of resonators as claimed in claim 21, means for exciting and sustaining their oscillations and means for generating a temperature-stable signal representative of the difference in oscillation frequencies of said resonators.

31. The time base as claimed in claim 29, wherein one of said resonators has a substantially higher oscillation frequency than the other, and said means for generating a temperature-stable signal further include a frequency divider circuit for reducing the highest frequency before said difference in the oscillation frequencies is taken.
